(19) United States
(12) Patent Application Publication
(10) Pub. No.: US 2009/0178820 A1
(43) Pub. Date: Jul. 16, 2009

(54) Television signal splitter casing

(75) Inventor: Jui-Huang Chung, Tou-Chen Chen (TW)

Correspondence Address: COOPER & DUNHAM, LLP, 30 Rockefeller Plaza, 20th Floor, NEW YORK, NY, 10112, US

(73) Assignee: Signal Cable System Co., Ltd.

(21) Appl. No.: 12/157,661

(22) Filed: Jun. 12, 2008

(30) Foreign Application Priority Data
Jan. 14, 2008 (TW) 097200802

(51) Int. Cl. H05K 5/00

(52) U.S. Cl. 174/50

(57) ABSTRACT

A television signal splitter casing has a body and a cover. The body is hollow and has a front, an opening and a groove. The opening is defined in the front and has an annular edge. The groove is formed in the annular edge of the opening and has an inner surface and multiple saw-teeth. The saw-teeth are formed on the inner surface of the groove. The cover is mounted securely on the opening of the body and has a brim. The brim is mounted in the groove of the body. The saw-teeth of the groove tightly bite and securely hold the brim. Therefore, the cover is mounted on the body without any soldering process so that the fabricating cost of the television signal splitter casing is low.

### BACKGROUND OF THE INVENTION

1. Field of the Invention

The present invention relates to a splitter casing, especially to be a television signal splitter casing that prevents electromagnetic interference (EMI) with nearby electronic devices.

2. Description of the Prior Arts

A television signal splitter is used to split a signal for two or more connectors so that televisions connected respectively to the connectors are able to receive the same signal simultaneously. With reference to FIG. 5, a conventional television signal splitter comprises a cover (91) and a casing (92). The cover (91) has a brim (93) and a slot (931). The slot (931) is formed in the brim (93) of the cover (91). The casing (92) has an opening and a mounting protrusion (94). The mounting protrusion (94) is formed around the opening of the casing (92) and engages the slot (931) of the cover (91). However, the fabricating cost of the television signal splitter is too high.

With reference to FIG. 6, another conventional television signal splitter comprises a casing (82) and a cover (81). The casing (82) has an opening and multiple saw-teeth (821). The saw-teeth (821) are formed on arranged in a loop around the opening of the casing (82). When the cover (81) is mounted on the opening of the casing (82), the saw-teeth (821) engage securely the cover (81). Although the fabricating cost of the conventional television signal splitter is lower, the engagement between the casing (82) and the cover (81) is not ideal. Because the saw-teeth (821) forming around the opening are pressed into the cover (81), the opening of the casing (82) probably expands and deforms inadvertently. Therefore, the expansion and deformation of the television signal splitter results in gaps between the casing (82) and the cover (81). The gaps of television signal splitter cause electromagnetic wave leakage interfering with nearby electronic devices.

With reference to FIG. 7, the other conventional television signal splitter comprises a casing (72) and a cover (71). The casing (72) combines with the cover (71) by soldering. The soldering fabrication of the television signal splitter is advantageous for electromagnetic interference (EMI) shielding. However, the soldering process wastes time and has a high cost.

To overcome the shortcomings, the present invention provides a television signal splitter to mitigate or obviate the aforementioned problems.

### SUMMARY OF THE INVENTION

The main objective of the present invention is to provide a television signal splitter casing that can be used to split a signal for two or more connectors and prevents EMI.

A television signal splitter casing in accordance with the present invention has a body and a cover. The body is hollow and has a front, an opening and a groove. The opening is defined in the front and has an annular edge. The groove is formed in the annular edge of the opening and has an inner surface and multiple saw-teeth. The saw-teeth are formed on the inner surface of the groove. The cover is mounted securely on the opening of the body and has a brim. The brim is mounted in the groove of the body. The saw-teeth of the groove tightly bite and securely hold the brim. Therefore, the cover is mounted on the body without any soldering process so that the fabricating cost of the television signal splitter casing is low.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a television signal splitter casing in accordance with the present invention;

FIG. 2 is an enlarged perspective view of the body in FIG. 1 without the cover;

FIG. 3 is an enlarged front view of the body in FIG. 1;

FIG. 4 is a cross sectional side view of the television signal splitter casing in FIG. 1;

FIG. 5 is a cross sectional side view of a conventional television signal splitter in accordance with the prior art;

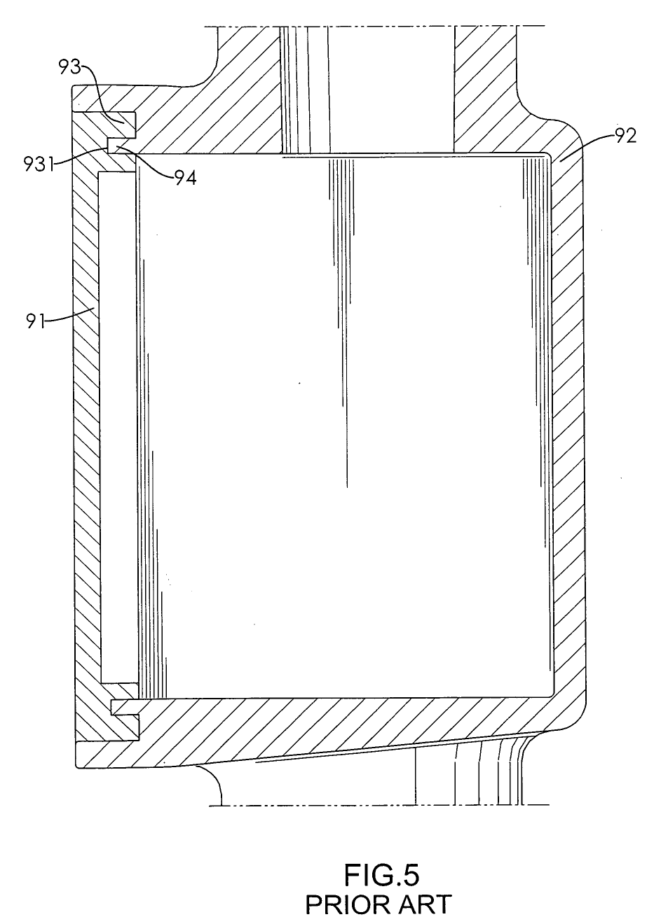

FIG. 6 is a cross sectional side view of another conventional television signal splitter in accordance with the prior art; and

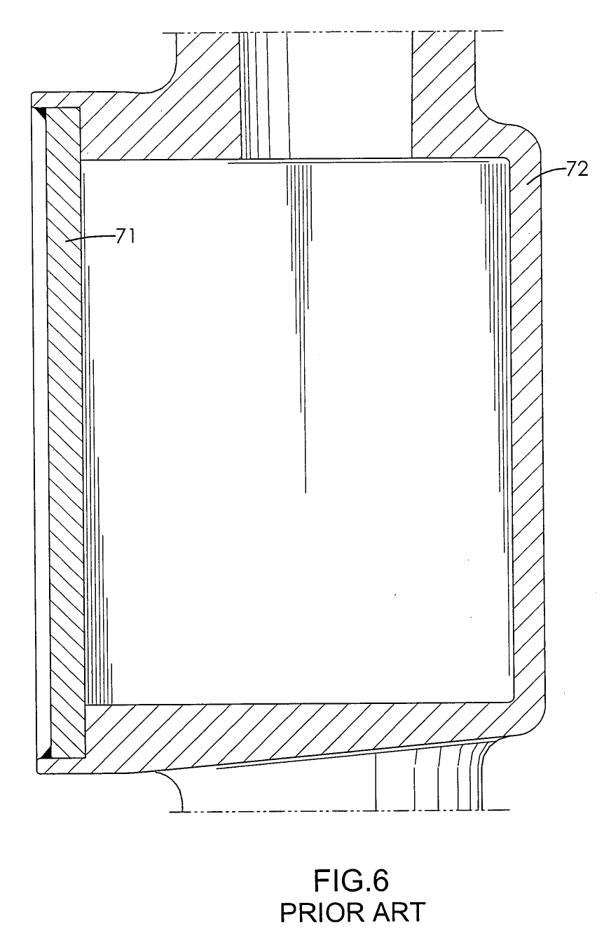

FIG. 7 is a cross sectional side view of another conventional television signal splitter in accordance with the prior art.

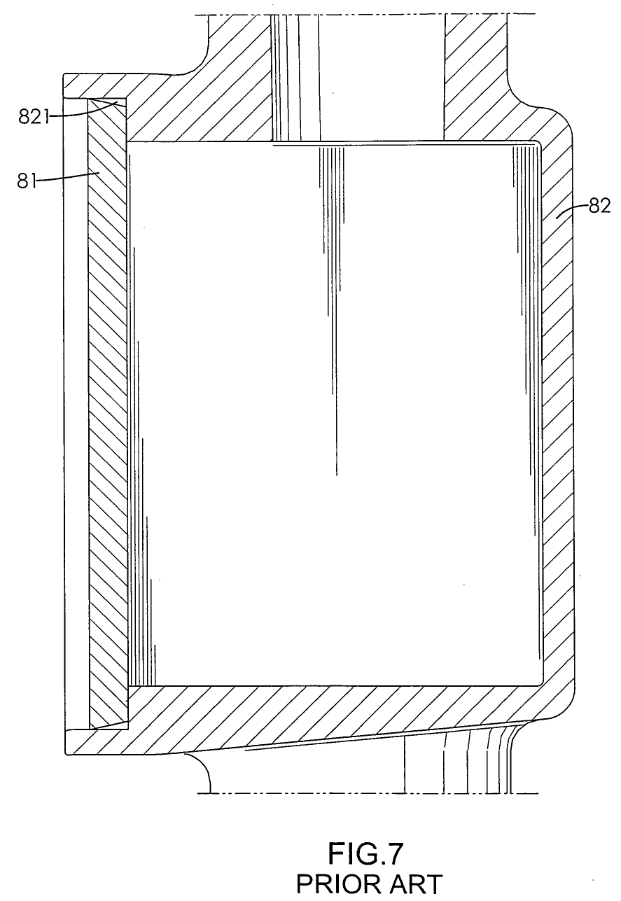

### DETAILED DESCRIPTION OF THE PREFERRED EMBODIMENTS

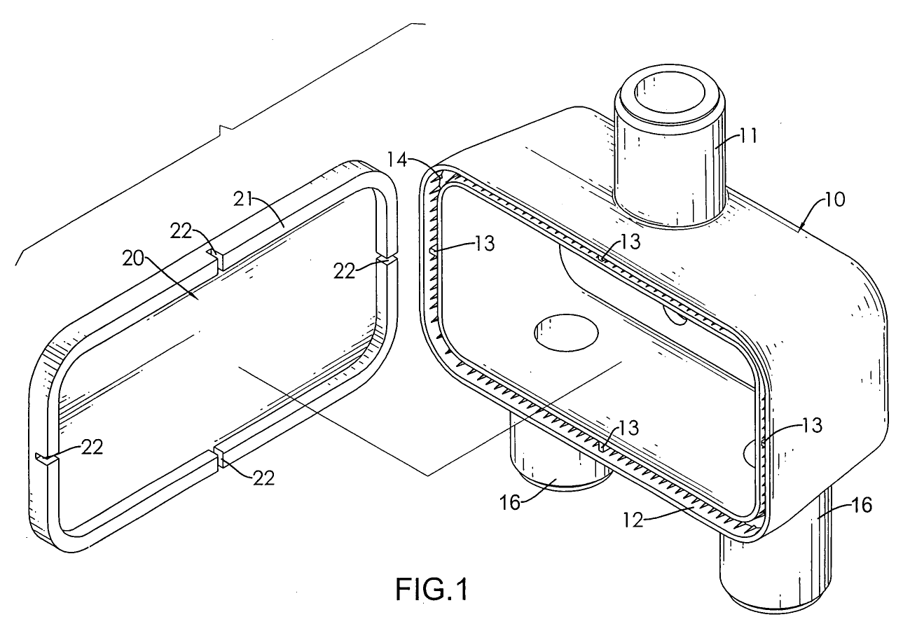

With reference to FIG. 1, a television signal splitter casing in accordance with the present invention comprises a body (10) and a cover (20).

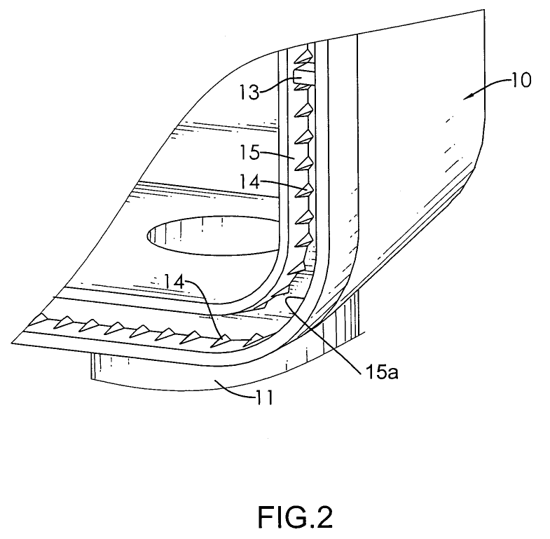

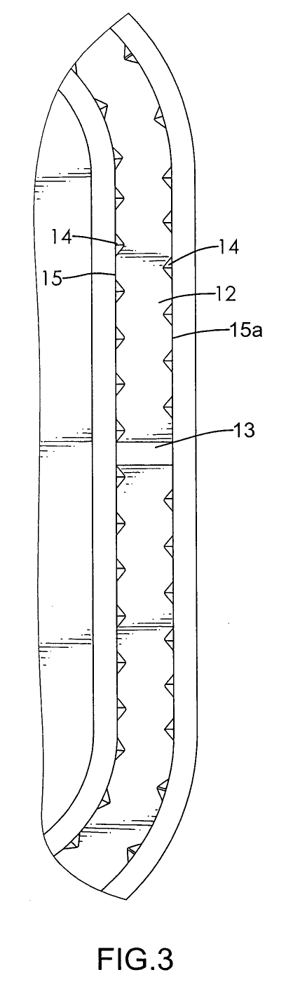

With reference to FIGS. 2 and 3, the body (10) is hollow and has a top, a bottom, a front, an opening, a cavity, an input connector (11), multiple output connectors (16) and a groove (12).

The opening is defined in the front and has an annular edge. The cavity is defined in the body (10) and communicates with the opening. The input connector (11) is formed on the top of the body (10). The output connectors (16) are formed on the bottom of the body (10). The groove (12) is annular and is formed in the annular edge of the opening and has an inner surface, multiple reinforcing tabs (13), multiple saw-teeth (14). The inner surface of the groove (12) has an annular inside surface (15) and an annular outside surface (15a) opposite to the annular inside surface (15). The reinforcing tabs (13) are formed transversely in the groove of the body (10) between the annular inside and outside surfaces (15, 15a) to strengthen the structure of the opening. The saw-teeth (14) are formed on the inner surface of the groove (12) and may be two loops of saw-teeth (14). The loops of the saw-teeth (14) are formed respectively on the annular inside and outside surfaces (15, 15a) of the groove (12) and are staggered to each other so that each saw-tooth (14) of one loop is aligned with an interval between two adjacent saw-teeth of the other loop. The staggered arrangement of the loops of the saw-teeth (14) evenly distributes the saw-teeth (14) in the groove (12) to perform an excellent engaging function with the cover (20) discussed hereafter.

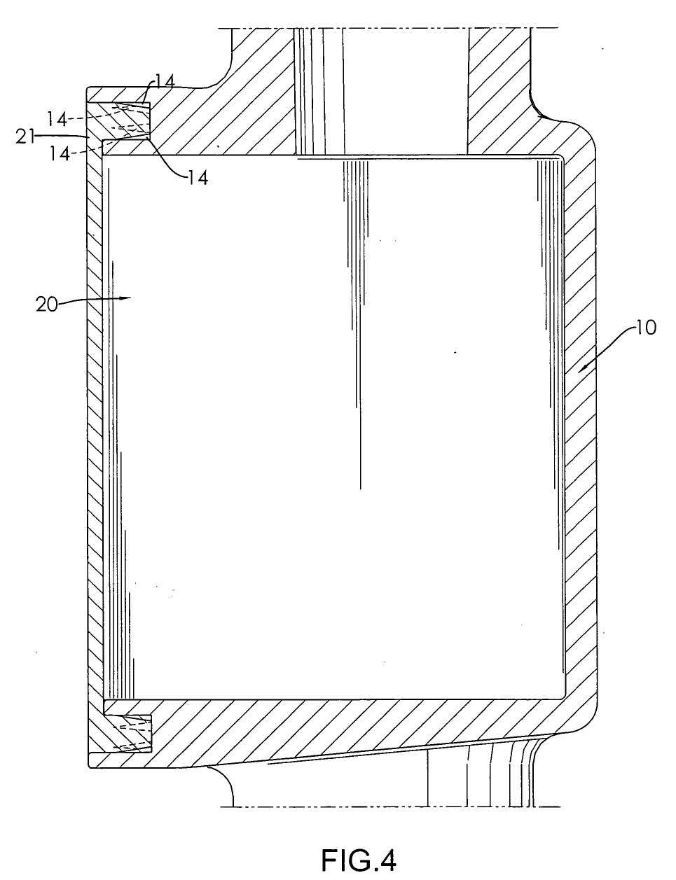

With reference to FIG. 4, the cover (20) is mounted securely on the opening of the body (10) and has a brim (21) and multiple notches (22). The brim (21) is annular and is mounted in the groove (12) of the body (10). The saw-teeth (14) of the groove (12) tightly bite and securely hold the brim (21). The notches (22) are formed transversely in the brim (21) and engage respectively the reinforcing tabs (13) of the body (10).

The saw-teeth (14) of the groove (12) tightly bite the brim (21) of the cover (20) so that the cover (20) is held securely in the opening of the body (10) without inadvertently dissembling. Furthermore, the reinforcing tabs (13) prevent the groove (12) of the body (10) from inadvertently expanding and deforming when the body (10) fabricates with the cover (20). Therefore, the cover (20) is well fitted in the body (10) without generating gaps to prevent the electromagnetic wave leakage that interferes with nearby electronic devices. Moreover, the cover (20) is mounted on the body (10) without any soldering process so that the fabricating cost of the television signal splitter casing is low.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A television signal splitter casing comprising
a body being hollow and having
a top;
a bottom;
a front;
an opening being defined in the front and having an annular edge;
a cavity being defined in the body and communicating with the opening;
an input connector being formed on the body;
multiple output connectors being formed on the body; and
a groove being annular and being formed in the annular edge of the opening and having
an inner surface having
an annular inside surface; and
an annular outside surface opposite to the annular inside surface; and
multiple saw-teeth being formed on the inner surface of the groove; and
a cover being mounted securely on the opening of the body and having
a brim being annular and being mounted in the groove of the body.

2. The television signal splitter casing as claimed in claim 1, wherein the saw-teeth are two loops of saw-teeth and the loops of the saw-teeth are formed respectively on the annular inside and outside surfaces of the groove and are staggered to each other so that each saw-tooth of one loop is aligned with an interval between two adjacent saw-teeth of the other loop.

3. The television signal splitter casing as claimed in claim 1, wherein
the groove further has multiple reinforcing tabs being formed transversely in the groove of the body between the annular inside and outside surfaces to strengthen the structure of the opening; and
the cover further has multiple notches being formed transversely in the brim and engaging respectively with the reinforcing tabs of the body.

4. The television signal splitter casing as claimed in claim 2, wherein
the groove further has multiple reinforcing tabs being formed transversely in the groove of the body between the annular inside and outside surfaces to strengthen the structure of the opening; and
the cover further has multiple notches being formed transversely in the brim and engaging respectively with the reinforcing tabs of the body.
